(19) United States
(12) Patent Application Publication
(10) Pub. No.: US 2012/0217596 A1
(43) Pub. Date: Aug. 30, 2012

(54) MAGNETIC TUNNEL JUNCTION AND METHOD FOR FABRICATING THE SAME

(76) Inventor: Ji Ho PARK, Changwon-si (KR)

(21) Appl. No.: 13/336,150

(22) Filed: Dec. 23, 2011

(30) Foreign Application Priority Data
Feb. 25, 2011 (KR) 10-2011-0017094

(51) Int. Cl. H01L 29/82; H01L 21/02

(52) U.S. Cl. 257/421; 438/3; 257/E29.323; 257/E21.002; 257/E43.005

(57) ABSTRACT

A magnetic tunnel junction includes a first magnetic layer, a tunnel insulating layer and a second magnetic layer. The first magnetic layer is formed on a substrate. The tunnel insulating layer is formed on the first magnetic layer. The second magnetic layer is formed on the tunnel insulating layer, where the second magnetic layer is shaped to be narrower at a center than at ends.

### CROSS-REFERENCE TO RELATED APPLICATIONS

The present application claims priority of Korean Patent Application No. 10-2011-0017094, filed on Feb. 25, 2011, which is incorporated herein by reference in its entirety.

### BACKGROUND

1. Field

Exemplary embodiments of the present invention relate to a magnetic tunnel junction and a method for fabricating the same, and more particularly, to a magnetic tunnel junction with a constant magnetization direction and a method for fabricating the same.

2. Description of the Related Art

A dynamic random access memory (DRAM) and a flash memory are representative semiconductor devices. As to their main characteristics, while the DRAM has a fast data processing speed because of its relatively easier data access, the DRAM are periodically refreshed to maintain stored data. On the other hand, while the flash memory stores nonvolatile data, the flash memory has a slow data processing speed because of its relatively difficult data access.

In producing semiconductor devices having advantages of both the DRAM and the flash memory, a spin transfer torque random access memory is being developed. The spin transfer torque random access memory is a semiconductor device using the quantum mechanical effect, i.e., magnetoresistance. Notably, the spin transfer torque random access memory has easier data access and the non-volatile storage of data storage.

The spin transfer torque random access memory includes a magnetic tunnel junction to store data. Generally, the magnetoresistance (MR) is changed depending on the magnetization direction between two ferromagnetic layers. The spin transfer torque random access memory senses a change in magnetoresistance and reads whether data stored in the magnetic tunnel junction is 1 or 0.

### SUMMARY

An embodiment of the present invention is directed to a magnetic tunnel junction with a constant magnetization direction and a method for fabricating the same.

In accordance with an embodiment of the present invention, a magnetic tunnel junction includes a first magnetic layer formed on a substrate, a tunnel insulating layer formed on the first magnetic layer, and a second magnetic layer formed on the tunnel insulating layer, wherein the second magnetic layer is shaped to be narrower at a center than at ends.

In accordance with another embodiment of the present invention, a memory device includes a first magnetic layer formed on a substrate, a tunnel insulating layer formed on the first magnetic layer and a second magnetic layer formed on the first magnetic layer, wherein the second magnetic layer is shaped to be narrower at a center than at ends.

In accordance with still another embodiment of the present invention, a method for fabricating a magnetic tunnel junction includes forming a magnetic tunnel junction layer having a first magnetic layer, a tunnel insulating layer and a second magnetic layer on a substrate, forming a first mask pattern on the magnetic tunnel junction layer, forming a magnetic tunnel junction pattern by etching the magnetic tunnel junction layer using the first mask pattern, forming a second mask pattern on the substrate having the magnetic tunnel junction formed thereon, and forming a magnetic tunnel junction by selectively etching sides of the magnetic tunnel junction pattern using the second mask pattern, where the magnetic tunnel junction is shaped to be narrower at a center than at ends.

### BRIEF DESCRIPTION OF THE DRAWINGS

FIG. 1 illustrates a plan view of a magnetic tunnel junction and a sectional view taken along line I-I′ of the magnetic tunnel junction.

FIG. 2 illustrates a plan view of a magnetic tunnel junction and a sectional view taken along line II-II′ of the magnetic tunnel junction in accordance with an embodiment of the present invention.

FIG. 3 illustrates a plan view of a magnetic tunnel junction and a sectional view taken along line III-III′ of the magnetic tunnel junction in accordance with another embodiment of the present invention.

FIGS. 4a and 4b illustrates magnetization directions of the magnetic tunnel junction of FIG. 3, particularly a second magnetic layer.

FIGS. 5a to 5d illustrate plan views of a magnetic tunnel junction and sectional views taken along line IV-IV′ of the magnetic tunnel junction, illustrating a method for fabricating the magnetic tunnel junction.

### DETAILED DESCRIPTION

Exemplary embodiments of the present invention will be described below in more detail with reference to the accompanying drawings. The present invention may, however, be embodied in different forms and should not be construed as limited to the exemplary embodiments set forth herein. These exemplary embodiments are provided so that this disclosure will be thorough and complete so as to enable a person of ordinary skill in the art to make and use the present invention. Throughout the disclosure, like reference numerals refer to like parts throughout the various figures and embodiments of the present invention.

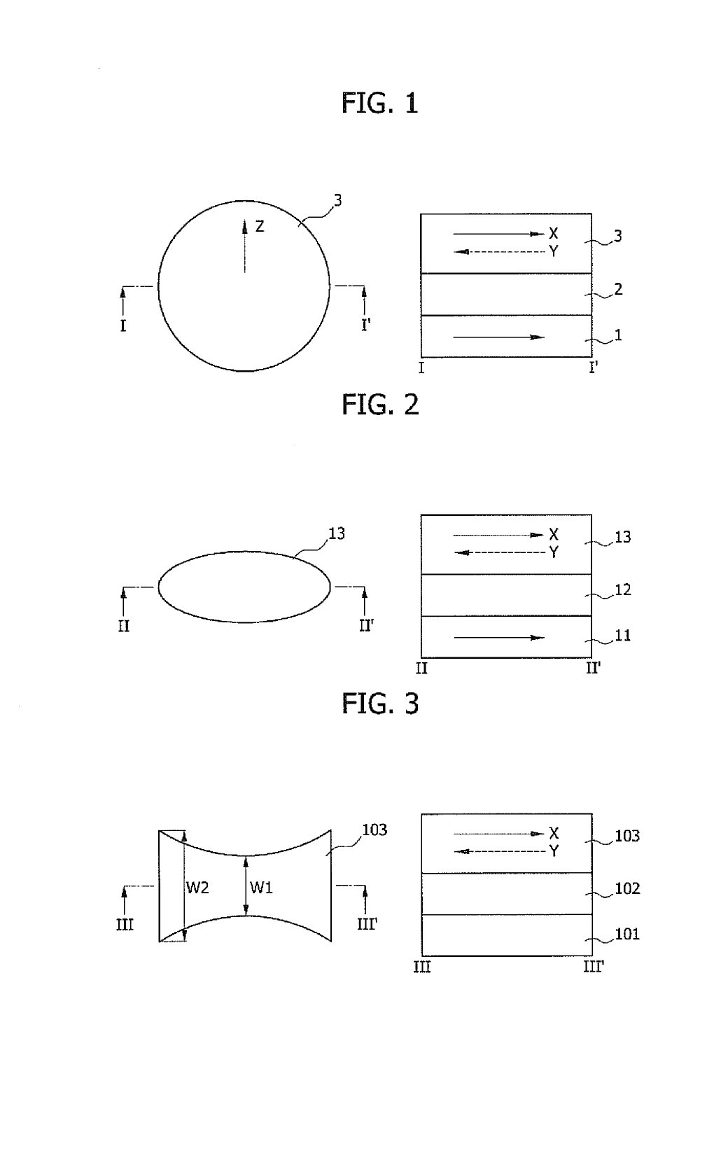

FIG. 1 illustrates a plan view of a magnetic tunnel junction and a sectional view taken along line I-I′ of the magnetic tunnel junction.

As illustrated in FIG. 1, the magnetic tunnel junction has a structure in which a first magnetic layer 1, a tunnel insulating layer 2 and a second magnetic layer 3 are sequentially laminated. The magnetic tunnel junction is fabricated in the shape of a cylinder. Here, the magnetization direction of the first magnetic layer 1 is fixed in a first direction X, and the magnetization direction of the second magnetic layer 3 is varied in the first direction X or a second direction Y depending on a direction of current supplied thereto. In this case, the resistance of the magnetic tunnel junction is decreased when the magnetization directions of the first and second magnetic layers 1 and 3 are the same, and the resistance of the magnetic tunnel junction is increased when the magnetization directions of the first and second magnetic layers 1 and 3 are opposite to each other. According to the detected resistance, the magnetic tunnel junction reads data.

In the second magnetic layer 3 having a varying magnetization direction, the magnetization direction is set in the first direction X or second direction X so that a change in magnetoresistance of the second magnetic layer 3 and the first magnetic layer 1 is accurately reflected. However, the magnetization direction of the second magnetic layer 3 is varied depending on the direction of current supplied thereto not only in the first and second directions X and Y but also in, for example, a third direction Z. This is because the second magnetic layer 3 has a circular shape. If the magnetization direction of the second magnetic layer 3 is not parallel to that of the first magnetic layer 1, the magnetoresistance of the second magnetic layer 3 and the first magnetic layer 1 is inaccurate, and therefore, the magnetic tunnel junction does not correctly store and read data.

FIG. 2 illustrates a plan view of a magnetic tunnel junction and a sectional view taken along line II-II′ of the magnetic tunnel junction in accordance with an embodiment of the present invention.

As illustrated in FIG. 2, the magnetic tunnel junction has a structure in which a first magnetic layer 11, a tunnel insulating layer 12 and a second magnetic layer 13 are sequentially laminated. The magnetic tunnel junction is fabricated in the shape of an elliptic cylinder. Here, the magnetization direction of the first magnetic layer 11 is fixed in a first direction X, and the magnetization direction of the second magnetic layer 13 is varied in the first direction X or a second direction Y depending on a direction of current supplied thereto. In this case, the resistance of the magnetic tunnel junction is decreased when the magnetization directions of the first and second magnetic layers 11 and 13 are the same, and the resistance of the magnetic tunnel junction is increased when the magnetization directions of the first and second magnetic layers 11 and 13 are opposite to each other. According to the detected resistance, the magnetic tunnel junction reads data.

Here, the second magnetic layer 13 is formed in an elliptic shape on a plane. That is, the width of the second magnetic layer 13 is greater than the height of the second magnetic layer 13. If the second magnetic layer 13 is formed in the elliptic shape as described above, the magnetization direction of the second magnetic layer 13 is formed in only the first direction X or second direction Y. This is based on the same principle that the magnetism of a bar magnet is concentrated on ends of the bar magnet and its magnetic direction extends in the extended direction of the bar magnet. For example, while the magnetization of a circular magnet may be formed in all different directions, the magnetization of the bar magnet runs along only the major axis direction.

The first magnetic layer 11 includes a diamagnetic layer referred to as a pinning layer and a ferromagnetic layer referred to as a pinned layer. The pinning layer functions to fix the magnetization direction of the pinned layer. The pinning layer is formed of a thin film made of at least one selected from the group consisting of IrMn, PtMn, MnO, MnS, MnTe, MnF₂, FeF₂, FeCl₂, FeO, CoCl₂, CoO, NiCl₂ and NiO. The magnetization direction of the pinned layer is fixed by the pinning layer. The pinned layer is formed of a thin film made of at least one selected from the group consisting of Fe, Cₒ, Ni, Gd, Dy, NiFe, CoFe, MnAs, MnBi, MnSb, CrO₂, MnOFe₂O₃, FeOFe₂O₃, NiOFe₂O₃, CuOFe₂O₃, EuO and Y₃Fe₅O₁₂.

The tunnel insulating layer 12 may be a MgO layer. Alternatively, the tunnel insulating layer 12 may be formed of a Group-IV semiconductor layer or may be formed by adding a Group-III or Group V element such as B, P or As to the Group-IV semiconductor layer so as to control the electric conductivity thereof.

The magnetization direction of the second magnetic layer 13 is changed depending on a direction of current supplied thereto. To this end, the second magnetic layer 13 is formed of a thin film made of at least one selected from the group consisting of Fe, Co, Ni, Gd, Dy, NiFe, CoFe, MnAs, MnBi, MnSb, CrO₂, MnOFe₂O₃, FeOFe₂O₃, NiOFe₂O₃, CuOFe₂O₃, EuO and Y₃Fe₅O₁₂.

FIG. 3 illustrates a plan view of a magnetic tunnel junction and a sectional view taken along line III-III′ of the magnetic tunnel junction in accordance with another embodiment of the present invention.

As illustrated in FIG. 3, the magnetic tunnel junction has a structure in which a first magnetic layer 101, a tunnel insulating layer 102 and a second magnetic layer 103 are sequentially laminated. The magnetic tunnel junction is fabricated in a shape that is extended in a first direction X and has a narrow center. Here, the magnetization direction of the first magnetic layer 101 is fixed in the first direction X, and the magnetization direction of the second magnetic layer 103 is varied in the first direction X or a second direction Y depending on a direction of current supplied thereto. In this case, the resistance of the magnetic tunnel junction is decreased when the magnetization directions of the first and second magnetic layers 101 and 103 are the same, and the resistance of the magnetic tunnel junction is increased when the magnetization directions of the first and second magnetic layers 101 and 103 are opposite to each other. According to the detected resistance, the magnetic tunnel junction reads data.

Here, the width W1 of a center of the second magnetic layer 103 is narrower than the width W2 of both ends of the second magnetic layer 103 on a plane. If the second magnetic layer 103 is formed in the shape described above, the magnetization direction of the second magnetic layer 103 is formed in only the first direction X or second direction Y. This is based on the same principle that the elliptic second magnetic layer 13 described above has only the first direction X or second direction Y.

While it has been illustrated in FIG. 3 that the magnetic tunnel junction is fabricated so that the first magnetic layer 101, the tunnel insulating layer 102 and the second magnetic layer 103 are all formed in a shape having a narrow center on a plane, the magnetic tunnel junction may be fabricated by forming the first magnetic layer 101 and the tunnel insulating layer 102 in an elliptic shape and then forming, for example, only the second magnetic layer 103 in a shape having a narrow center.

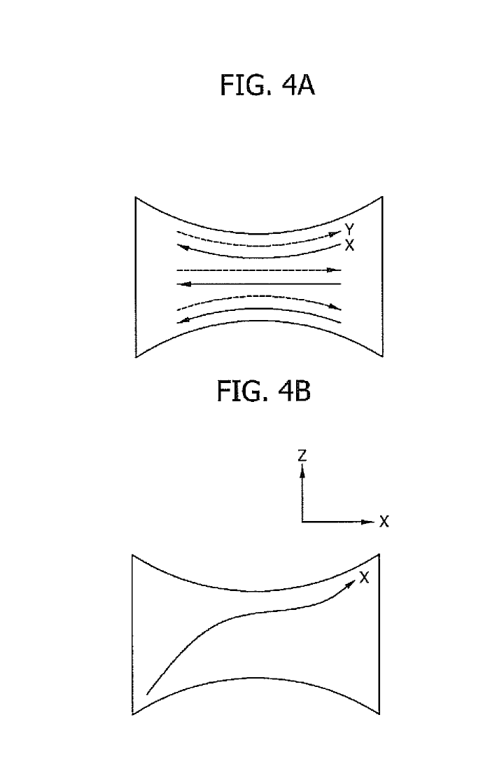

FIGS. 4a and 4b illustrate magnetization directions of the magnetic tunnel junction of FIG. 3, particularly the second magnetic layer 103.

As illustrated in FIG. 4a, the magnetization of the second magnetic layer 103 is formed in, for example, only the first and second directions X and Y due to the narrow width W1 of the center of the second magnetic layer 103. In FIG. 4b, the magnetization of the second magnetic layer 103 tends to be formed more in the first direction Z before being corrected to be in the direction of X along a side of the center with the narrow width W1. Thus, if the second magnetic layer 103 is formed in a shape having a narrow center, the magnetization direction of the second magnetic layer 103 is formed in, for example, only the first and second directions X and Y. Thus, the magnetization direction of the second magnetic layer 103 is parallel to that of the first magnetic layer 101, fixed in the first direction X.

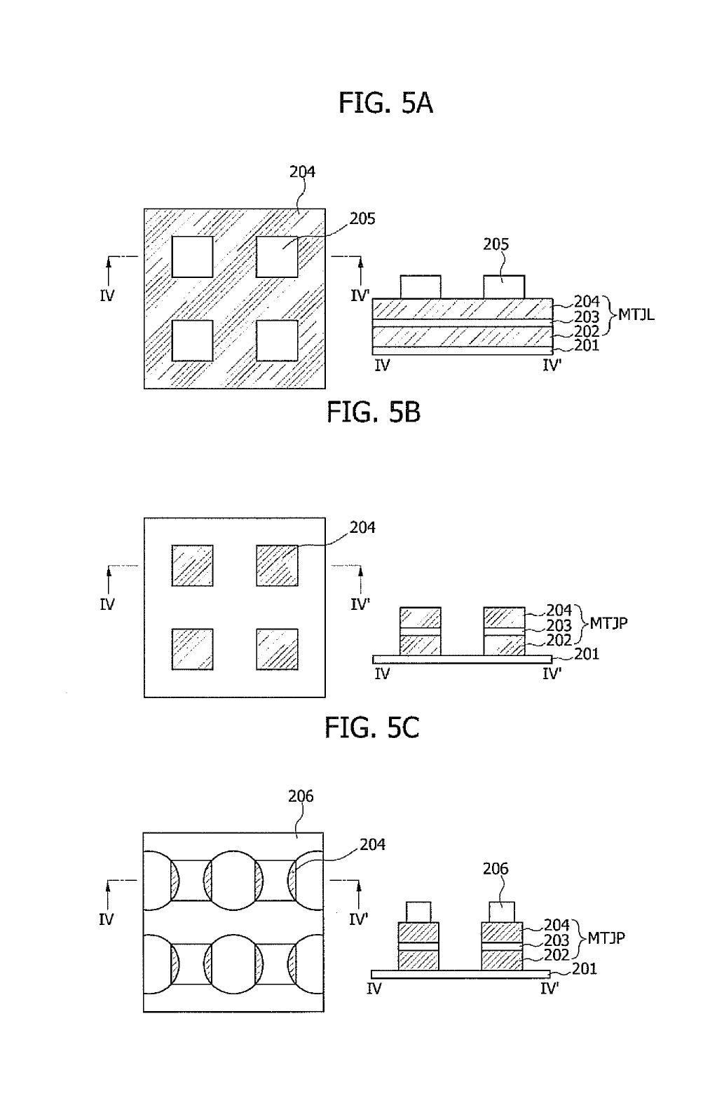

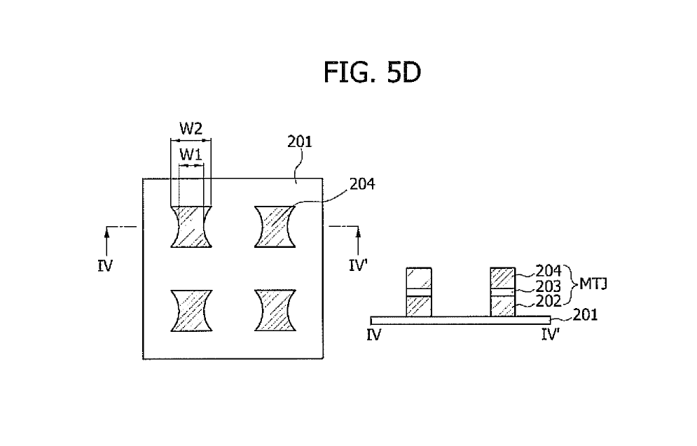

FIGS. 5a to 5d illustrate plan views of a magnetic tunnel junction and sectional views taken along line IV-IV′ of the magnetic tunnel junction, illustrating a method for fabricating the magnetic tunnel junction.

As illustrated in FIG. 5a, a magnetic tunnel junction layer MTJL is formed by laminating a first magnetic layer 201, a tunnel insulating layer 203 and a second magnetic layer 204 on a substrate having a bottom layer 201 formed thereon.

The bottom layer 201 includes a transistor for selecting a magnetic tunnel junction and a contact plug for connecting a junction area at one side of the transistor and the magnetic tunnel junction.

The first magnetic layer 201 includes a diamagnetic layer referred to as a pinning layer and a ferromagnetic layer referred to as a pinned layer. The pinning layer functions to fix the magnetization direction of the pinned layer. To this end, the pinning layer is formed of a thin film made of at least one selected from the group consisting of IrMn, PtMn, MnO, MnS, MnTe, MnF₂, FeF₂, FeCl₂, FeO, CoCl₂, CoO, NiCl₂ and NiO. The magnetization direction of the pinned layer is fixed by the pinning layer. To this end, the pinned layer is formed of a thin film made of at least one selected from the group consisting of Fe, Co, Ni, Gd, Dy, NiFe, CoFe, MnAs, MnBi, MnSb, CrO₂, MnOFe₂O₃, FeOFe₂O₃, NiOFe₂O₃, CuOFe₂O₃, EuO and Y₃Fe₅O₁₂.

The tunnel insulating layer 203 may be a MgO layer. Alternatively, the tunnel insulating layer 203 may be formed of a Group-IV semiconductor layer, or may be formed by adding a Group-III or Group V element such as B, P or As to the Group-IV semiconductor layer so as to control the electric conductivity thereof.

The magnetization direction of the second magnetic layer 204 is changed depending on a direction of current supplied thereto. To this end, the second magnetic layer 204 is formed of a thin film made of at least one selected from the group consisting of Fe, Co, Ni, Gd, Dy, NiFe, CoFe, MnAs, MnBi, MnSb, CrO₂, MnOFe₂O₃, FeOFe₂O₃, NiOFe₂O₃, CuOFe₂O₃, EuO and Y₃Fe₅O₁₂.

Subsequently, a first mask pattern 205 is formed on the second magnetic layer 204. In this case, the second magnetic layer 204 may be patterned by interposing a hard mask layer between the first mask pattern 205 and the second magnetic layer 204.

The first mask pattern 205 is a square-hole-type mask pattern. Accordingly, the first mask pattern 205 is formed in a square shape on a region in which a magnetic tunnel junction is to be formed.

As illustrated in FIG. 5b, a magnetic tunnel junction pattern MTJP is formed by etching the second magnetic layer 204, the tunnel insulating layer 203 and the first magnetic layer 202 using the first mask pattern 205 as an etch barrier. Since the first mask pattern 205 is the square-hole-type mask pattern, the magnetic tunnel junction pattern MTJP is formed in the shape of a square pillar.

As illustrated in FIG. 5c, a second mask pattern 206 is formed on the substrate having the magnetic tunnel junction pattern MTJP formed thereon.

The second mask pattern 206 is a circle-hole-type mask pattern. Accordingly, in the second mask pattern 206, a circular hole is formed between regions in which magnetic tunnel junctions are to be formed. Thus, centers of both sides of the magnetic tunnel junction pattern MTJP are exposed to the outside by the circular hole.

As illustrated in FIG. 5d, a magnetic tunnel junction MTJ is formed by etching the exposed magnetic tunnel junction pattern MTJP using the second mask pattern 206 as an etch barrier.

As described above, the centers of both sides of the magnetic tunnel junction pattern MTJP are exposed to the outside by the second mask pattern 206, and the magnetic tunnel junction MTJ is then formed etching the centers of both sides of the magnetic tunnel junction pattern MTJP. Thus, the width W1 of the center of the magnetic tunnel junction MTJ is formed narrower than that W2 at sides of the magnetic tunnel junction MTJ.

In accordance with the embodiments of the present invention, the magnetic tunnel junction, particularly the second magnetic layer (free magnetization layer) is fabricated in an elliptic shape or shape having a narrow center so that the magnetization direction of the magnetic tunnel junction is formed in a constant direction. If the second magnetic layer is formed as described above, the magnetization direction of the second magnetic layer is formed in a constant direction. Accordingly, since the magnetization direction of the second magnetic layer is formed in, for example, only the first and second directions X and Y, the magnetization direction of the second magnetic layer is parallel to that of the first magnetic layer, fixed in the first direction X.

In accordance with the present invention, the magnetic tunnel junction is fabricated in a shape that is extended in one direction and has a center having a width narrower than at ends of the shape. If the magnetic tunnel junction is formed as described above, the magnetization direction of the magnetic tunnel junction is formed in a constant direction. Thus, a more accurate change in magnetoresistance of the magnetic tunnel junction may be obtained. Thus, reliability for data reading of a spin transfer torque random access memory including the magnetic tunnel junction may be obtained.

While the present invention has been described with respect to the specific embodiments, it will be apparent to those skilled in the art that various changes and modifications may be made without departing from the spirit and scope of the invention as defined in the following claims.

What is claimed is:

1. A magnetic tunnel junction, comprising:
a first magnetic layer formed on a substrate;
a tunnel insulating layer formed on the first magnetic layer; and
a second magnetic layer formed on the tunnel insulating layer,
wherein the second magnetic layer is shaped to be narrower at a center than at ends.

2. The magnetic tunnel junction of claim 1, wherein the first magnetic layer and the tunnel insulating layer has the same shape as the second magnetic layer.

3. The magnetic tunnel junction of claim 1, wherein the first magnetic layer includes a diamagnetic layer and a ferromagnetic layer.

4. The magnetic tunnel junction of claim 3, wherein the diamagnetic layer includes at least one selected from the group consisting of IrMn, PtMn, MnO, MnS, MnTe, MnF₂, FeF₂, FeCl₂, FeO, CoCl₂, CoO, NiCl₂ and NiO.

5. The magnetic tunnel junction of claim 3, wherein the ferromagnetic layer includes at least one selected from the group consisting of Fe, Co, Ni, Gd, Dy, NiFe, CoFe, MnAs, MnBi, MnSb, CrO₂, MnOFe₂O₃, FeOFe₂O₃, NiOFe₂O₃, CuOFe₂O₃, EuO and Y₃Fe₅O₁₂.

6. The magnetic tunnel junction of claim 1, wherein the second magnetic layer includes at least one selected from the group consisting of Fe, Co, Ni, Gd, Dy, NiFe, CoFe, MnAs, MnBi, MnSb, CrO₂, MnOFe₂O₃, FeOFe₂O₃, NiOFe₂O₃, CuOFe₂O₃, EuO and Y₃Fe₅O₁₂.

7. A memory device comprising:
a first magnetic layer formed on a substrate;
a tunnel insulating layer formed on the first magnetic layer; and
a second magnetic layer formed on the first magnetic layer, wherein the second magnetic layer is shaped to be narrower at a center than at ends.

8. The memory device of claim 7, wherein the first magnetic layer and the tunnel insulating layer has the same shape as the second magnetic layer.

9. The memory device of claim 7, wherein the first magnetic layer includes a diamagnetic layer and a ferromagnetic layer.

10. The memory device of claim 9, wherein the diamagnetic layer includes at least one selected from the group consisting of IrMn, PtMn, MnO, MnS, MnTe, MnF₂, FeF₂, FeCl₂, FeO, CoCl₂, CoO, NiCl₂ and NiO.

11. The memory device of claim 9, wherein the ferromagnetic layer includes at least one selected from the group consisting of Fe, Co, Ni, Gd, Dy, NiFe, CoFe, MnAs, MnBi, MnSb, CrO₂, MnOFe₂O₃, FeOFe₂O₃, NiOFe₂O₃, CuOFe₂O₃, EuO and Y₃Fe₅O₁₂.

12. The memory device of claim 7, wherein the second magnetic layer includes at least one selected from the group consisting of Fe, Co, Ni, Gd, Dy, NiFe, CoFe, MnAs, MnBi, MnSb, CrO₂, MnOFe₂O₃, FeOFe₂O₃, NiOFe₂O₃, CuOFe₂O₃, EuO and Y₃Fe₅O₁₂.

13. The memory device of claim 7, wherein the second magnetic layer has an elongated shape with a minor axis and a major axis and a magnetic direction of the second magnetic layer is fixed to run in the direction of the major axis.

14. The memory device of claim 13, wherein the elongated shape has a progressively larger width as the shape extends farther away from a center of the major axis.

15. A method for fabricating a magnetic tunnel junction, the method comprising:
forming a magnetic tunnel junction layer having a first magnetic layer, a tunnel insulating layer and a second magnetic layer on a substrate;
forming a first mask pattern on the magnetic tunnel junction layer;
forming a magnetic tunnel junction pattern by etching the magnetic tunnel junction layer using the first mask pattern;
forming a second mask pattern on the substrate having the magnetic tunnel junction formed thereon; and
forming a magnetic tunnel junction by selectively etching sides of the magnetic tunnel junction pattern using the second mask pattern, wherein the magnetic tunnel junction is shaped to be narrower at a center than at ends.

16. The method of claim 15, wherein the first mask pattern is formed to have a square-hole to expose a region in which the magnetic tunnel junction is to be formed.

17. The method of claim 15, wherein the second mask pattern is formed to have a circular hole to expose a side of the magnetic tunnel junction.

18. The method of claim 15, wherein the magnetic tunnel junction has an elongated shape.
